(19) United States
(12) Patent Application Publication
(10) Pub. No.: US 2004/0090221 A1
(43) Pub. Date: May 13, 2004

(54) Device and method for testing electronic components

(76) Inventor: Antoon Willem Pothoven, Gendt (NL)

Correspondence Address: John W Mcllvaine, 700 Koppers Building, 436 Seventh Avenue, Pittsburgh, PA, 15219-1818, US

(21) Appl. No.: 10/466,388

(22) PCT Filed: Jan. 16, 2002
(86) PCT No.: PCT/NL02/00029

(30) Foreign Application Priority Data
Jan. 16, 2001 (NL) 1017121
Feb. 2, 2001 (NL) 1017272

(51) Int. Cl. G01R 1/00

(52) U.S. Cl. 324/158.1

(57) ABSTRACT

The invention relates to a device for testing electronic components, comprising: a testing head, and means for bringing the components for testing into contact with the testing head, characterized in that the means for bringing the components for testing into contact with the testing head comprise at least two positioning units which are adapted for co-action with the common testing head. The invention also relates to a method for performing a test measurement.

The invention relates to a device for testing electronic components, comprising: a testing head and means for bringing the components for testing into contact with the testing head. The invention also relates to a method for testing electronic components.

In the testing of electronic components according to the prior art, use is generally made of a testing head provided with a large number of electrically conducting contacts. The test contacts are connected to an electronic testing mechanism. In order to perform a test measurement a component for testing is gripped by a manipulator and then positioned. The positioning is also referred to as indexing. Because of the large number of electrically conducting test contacts and the large quantity of generally very compactly arranged contact points on the component(s) for testing, positioning must take place very precisely. Once the component(s) has (have) been positioned sufficiently accurately, the component(s) is (are) brought into contact with the test contacts by the manipulator, whereafter the actual testing is performed. A method and device for testing electronic components which functions according to the above described prior art are shown inter alia in the international patent application WO 99/49328. A drawback of the prior art methods and devices is that the production capacity of a generally expensive testing head with peripheral equipment (prices in excess of one million Euros are not unusual) is utilized to only a limited extent.

The present invention has for its object to increase the available capacity of a testing head with peripheral equipment while retaining the advantages of the prior art.

The invention provides for this purpose a device of the type stated in the preamble, characterized in that the means for bringing the components for testing into contact with the testing head comprise at least two positioning units which are adapted for co-action with the common testing head. To this end the positioning devices are preferably adapted to position the electronic components in a plane and the testing device is also provided with common pressing means for bringing the electronic components into contact with the testing head. By means of the device according to the invention it is possible to load respectively offload one of a plurality of positioning units while another positioning unit which is loaded with a component for testing can be utilized at that moment to perform a test measurement. Loading and offloading of the positioning units thus no longer need form part of the critical path of processing which defines the minimum cycle time of a test measurement. As a result the relatively costly production capacity of the testing head with peripheral equipment can be better utilized than in the prior art. Further advantages are gained by separating the functions of “positioning” and “bringing into contact with the testing head” of the electronic components. The positioning units can hereby take a relatively light form, which enhances maximum positioning speed and limits the costs of the multiple positioning units. The placing into contact with the testing heads often has to involve considerable pressure (generally more than 1000 N) which can be produced by pressing means which take a relatively heavy form and only need to take a single form. Since the two required functions of “positioning” and “bringing into contact with the testing head” require considerably different specifications of the drive means, it is possible by dividing this function among different components of the device to optimize the individual components in accordance with the performance to be produced. This improves the quality, limits the time required for the purpose and reduces the costs of the individual functions. The device is particularly intended for testing of electronic components, a plurality of which are mounted on a carrier and wherein the carrier is displaced with the plurality of components. The device can however also be used for individual manipulation and testing of components.

In order to limit the costs thereof, the positioning means are preferably provided with only a limited number of degrees of freedom of movement. In an advantageous embodiment variant the positioning units are displaceable with three degrees of freedom in a plane (linear X and Y direction and angular displacement). The pressing means are then preferably displaceable perpendicularly of this positioning plane. The positioning plane thus lies some distance from the testing head so that no disadvantageous interference in the separate functions can occur: All this can be realized structurally with limited effort.

In yet another preferred embodiment the testing device is provided with blowing means for generating an overpressure between the positioning units and the pressing means for gas bearing of the positioning units relative to a carrying surface of the pressing means. A gas bearing (generally by means of an overpressure of air) makes other means unnecessary for bearing the positioning units relative to the pressing means; because of the required relative displaceability a particular form of bearing is in any case desirable. By dispensing with mechanical bearing means such as rollers, bearings and the like the construction can remain simple and relatively light. In addition, such a gas bearing prevents an electronic component from deforming when it comes into contact with the testing head (in particular bending of the component for testing is prevented), since the component can be supported over its entire surface. When the testing device also comprises at least one guide surface which can connect onto a carrying surface of the pressing means for transporting the individual positioning units to the carrying surface of the pressing means and transporting them away from the carrying surface of the pressing means, the displacement of the positioning units to and from the pressing means is further simplified. Another advantage of this constriction is that the positioning units are permanently supported, which makes it possible for the positioning units to take an even lighter form, as they do not have to be self-supporting.

For automated feed and discharge of components the positioning units are preferably connectable to feed and discharge means for electronic components. An example hereof is a robot arm or other type of conveyor.

In yet another embodiment variant the testing device is also provided with visual inspection means for monitoring the position of a component for inspecting relative to a positioning unit and/or relative to the testing head. The visual inspection can be directed at the position of the positioning unit or parts thereof and the position of the component for inspecting. A significant aspect of the visual inspection is that, given this embodiment, it can take place as an operation which does not affect the cycle time. After a visual inspection the result of the monitoring can be employed to control the device, in particular to control the positioning units. Since a renewed visual inspection can be carried out during each cycle, the reproducible accuracy of the device is less relevant, since the positioning of a positioning unit and/or of a component can be regulated separately per production run. A further advantage of positioning a positioning unit and/or a component per production run is that the device can function independently of temperature; expansion differences resulting from temperature change can be compensated by control of the device which is subject to a visual inspection per production cycle. In addition to an inspection for positioning, the visual inspection means can also be used for a visual product inspection. The test options of the testing device are thus further increased.

For accurate and automated operation the testing device according to the invention is preferably provided with drive means for displacing the positioning units and the pressing means, which drive means are regulated by at least one central control unit.

The invention also provides an assembly of at least one testing device as described above and a manipulator for feed and discharge of electronic components. The manipulator can herein be formed by a robot or other type of conveyor. It is also possible for the assembly to also comprise at least one other processing unit for electronic components. Examples of other processing devices are a heating module for preheating components for testing, another testing device, a laser-labelling device for labelling tested components and so on. When the testing device, or a part thereof, is enclosed by a temperature-insulating housing, preheated (or cooled) components can be tested at a more or less constant temperature. When the testing device is applied in an environment with a non-constant temperature it is particularly advantageous to provide it with visual inspection means for an active regulation during positioning of components for testing.

In addition, the invention provides a method for testing electronic components, comprising the steps of: a) feeding an electronic component for testing to one of a plurality of positioning units, b) displacing the positioning unit provided with an electronic component to common pressing means, c) displacing the positioning unit provided with an electronic component with the common pressing means such that the electronic component makes contact with a testing head, and d) performing a test measurement. After performing of the test measurement as according to processing step D), the electronic component is carried a distance away from the testing head by means of the common pressing means during a subsequent processing step E). By means of this method the advantages can be obtained as already described with reference to the device according to the present invention.

For a large number of (usually assembled) components it is not sufficient to place the electronic component(s) into contact with the testing head only once. Product carriers often contain for instance a plurality of semiconductors (chips) containing many contact points: The most complex testing heads have “only” 1064 contact pins, and a carrier (leadframe, BGA and the like) with a plurality of semiconductors must normally be placed in repeated contact with the testing head for full testing of all components. For this purpose an electronic component preferably passes through the processing steps c) and d) once again after performing of the processing step E). After being carried a distance away from the testing head, the electronic component is preferably discharged by the positioning unit by means of processing step e).

The method according to the invention makes it possible during performing of any of the processing steps a) to e) for an electronic component for testing to be loaded and/or offloaded onto/from a positioning unit not involved in these processing steps. Loading respectively offloading of the positioning unit does not therefore restrict the cycle time of a test measurement to be carried out.

The present invention will be further elucidated with reference to the non-limitative embodiments shown in the following figures. Herein:

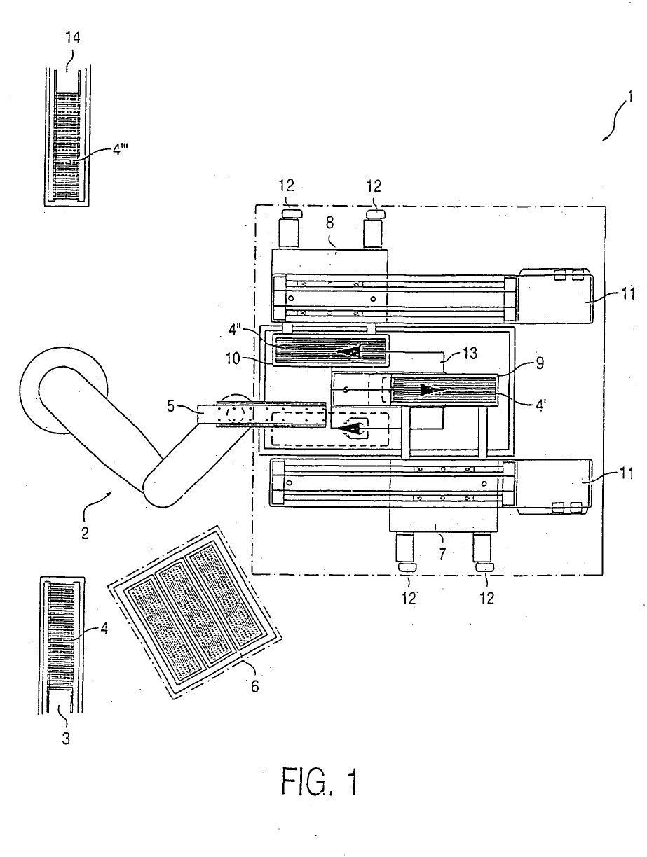

FIG. 1 shows a top view of an assembly of a testing device according to the invention and a robot, and

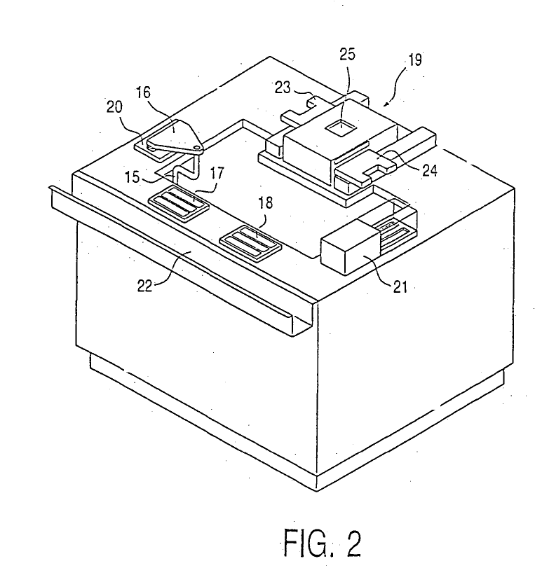

FIG. 2 shows a perspective view of an alternative embodiment of an assembly according to the invention.

FIG. 1 shows in top view a testing device 1 and a robot 2 co-acting therewith. Components 4 for testing are supplied by means of a feed track 3. The supplied components 4 are then gripped by a gripper head 5 of robot 2 and displaced thereby to testing device 1. Before placing thereof in testing device 1, the components 4 for testing can optionally be preheated on a heating plate 6.

Testing device 1 is provided with two positioning units 7,8 which can both be loaded by gripper head 5. Robot 2 will load the positioning unit 7,8 which is empty. Each positioning unit 7,8 is provided with a table 9,10 which is displaceable in the plane of view by means of electric motors 11,12. Positioning units 9,10 are moved separately in the loaded state to a position above in this case vertical pressing means, only the upper surface 13 of which is visible in this figure. The upper surface 13 is displaceable perpendicularly of the plane of view such that a table 9,10 situated above upper surface 13 is displaced upward until the component 4 lying on the table is carried with sufficient force into contact with a measuring head disposed above upper surface 13. After the measurement has been performed, the tested component 4′ is moved by displacing the relevant table 9 to a position at a distance from upper surface 13. A following component 4″ can now be carried by table 10 to a position above the upper surface 13 so as to be tested, while table 9 can simultaneously be offloaded and re-loaded with a new component 4 for testing. The tested components 4′″ are displaced by robot 2 to a discharge track 14.

FIG. 2 shows a perspective view of an assembly of a robot arm 15 with a gripper head 16, feed and outfeed stations 17,18, a testing device 19 and diverse peripheral devices 20,21. The robot arm displaces components for testing from the feed station 17, which is supplied by means of transport track 22, optionally via one or more stations with peripheral devices 20,21, to the testing device 19 where the process takes place as specified with reference to FIG. 1. Shown clearly are the tables 23,24 displaceable in a plane and the schematically shown testing head 25.

1. Device for testing electronic components, comprising:
a testing head, and
means for bringing the components for testing into contact with the testing head,
characterized in that
the means for bringing the components for testing into contact with the testing head comprise at least two positioning units which are adapted for co-action with the common testing head.

2. Testing device as claimed in claim 1, characterized in that the positioning devices are adapted to position the electronic components in a plane and that the testing device is also provided with common pressing means for bringing the electronic components into contact with the testing head.

3. Testing device as claimed in claim 2, characterized in that the pressing means are displaceable perpendicularly of the positioning plane.

4. Testing device as claimed in claim 2 or 3, characterized in that the testing device is provided with blowing means for generating an overpressure between the positioning units and the pressing means for gas bearing of the positioning units relative to a carrying surface of the pressing means.

5. Testing device as claimed in any of the claims 2-4, characterized in that the testing device also comprises at least one guide surface which can connect onto a carrying surface of the pressing means for transporting the individual positioning units to the carrying surface of the pressing means and transporting them away from the carrying surface of the pressing means.

6. Testing device as claimed in any of the claims 2-5, characterized in that the positioning units are connectable to feed and discharge means for electronic components.

7. Testing device as claimed in any of the foregoing claims, characterized in that the testing device is also provided with visual inspection means for monitoring the position of a component for inspecting relative to a positioning means.

8. Testing device as claimed in any of the foregoing claims, characterized in that the testing device is also provided with visual inspection means for monitoring the position of a positioning means relative to the testing head.

9. Testing device as claimed in any of the foregoing claims, characterized in that the testing device is provided with drive means for displacing the positioning units and the pressing means, which drive means are regulated by at least one central control unit.

10. Assembly of at least one testing device as claimed in any of the foregoing claims and a manipulator for feed and discharge of electronic components.

11. Assembly as claimed in claim 10, characterized in that the manipulator is formed by a robot.

12. Assembly as claimed in claim 10 or 11, characterized in that the assembly also comprises at least one other processing unit for electronic components.

13. Assembly as claimed in any of the claims 10-12, characterized in that the testing device is enclosed by a temperature-insulating housing.

14. Method for testing electronic components, comprising the steps of:
A) feeding an electronic component for testing to one of a plurality of positioning units,
B) displacing the positioning unit provided with an electronic component to common pressing means,
C) displacing the positioning unit provided with an electronic component with the common pressing means such that the electronic component makes contact with a testing head, and
D) performing a test measurement.

15. Method as claimed in claim 14, characterized in that after performing of the test measurement as according to processing step D), the electronic component is carried a distance away from the testing head by means of the common pressing means during a subsequent processing step E).

16. Method as claimed in claim 15, characterized in that the electronic component passes through the processing steps C) and D) once again after performing of the processing step E).

17. Method as claimed in claim 15 or 16, characterized in that after being carried a distance away from the testing head, the electronic component is discharged by the positioning unit by means of processing step E).

18. Method as claimed in any of the claims 14-17, characterized in that during performing of any of the processing steps A) to E) a positioning unit not involved in these processing steps is loaded with an electronic component for testing.

19. Method as claimed in any of the claims 14-18, characterized in that during performing of any of the processing steps A) to E) a tested electronic component is offloaded from a positioning unit not involved in these processing steps.
